(19) United States
(12) Patent Application Publication
(10) Pub. No.: US 2005/0218407 A1
(43) Pub. Date: Oct. 6, 2005

(54) Array substrate, liquid crystal display device and method of manufacturing array substrate

(76) Inventors: Yuki Matsuura, Kitakatsushika-gun (JP); Arichika Ishida, Okegawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/141,025

(22) Filed: Jun. 1, 2005

Related U.S. Application Data
(63) Continuation of application No. PCT/JP04/11610, filed on Aug. 12, 2004.

(30) Foreign Application Priority Data
Aug. 18, 2003 (JP) 2003-294583

(51) Int. Cl. H01L 29/786; H01L 21/84

(52) U.S. Cl. 257/66; 438/155; 438/164; 257/71

(57) ABSTRACT

A gate insulating film is formed on a glass substrate on which a plurality of polysilicon films are formed as islands. A first meal layer formed on the gate insulating film is patterned to form gate electrodes on the gate insulating film facing a polysilicon layer which gives rise to thin film transistors. A second metal layer is formed on the gate insulating film to cover the gate electrodes. Wiring portions are stacked on the gate electrodes of the thin film transistors.

### CROSS REFERENCE TO RELATED APPLICATIONS

This is a Continuation Application of PCT Application No. PCT/JP2004/011610, filed Aug. 12, 2004, which was published under PCT Article 21(2) in Japanese.

This application is based upon and claims the benefit of priority from prior Japanese Patent Application No. 2003-294583, filed Aug. 18, 2003, the entire contents of which are incorporated herein by reference.

### BACKGROUND OF THE INVENTION

1. Field of the Invention

The present invention relates to an array substrate including a switching element, a liquid crystal display device and a method of manufacturing the array substrate.

2. Description of the Related Art

In recent years, as the liquid crystal display device, a system-type liquid crystal device has been commercially available. In the system-type liquid crystal, not only simple drive circuits, that is, an X driver circuit and Y driver circuit, but also even an external circuit such as a DAC (digital-to-analog converter) circuit, which is conventionally mounted by TAB (tape automated bonding) are built on one main surface of its glass substrate, and a memory function such as SRAM or DRAM and optical sensor are built.

A liquid crystal display device of this type requires a thin film transistor as a high performance switching element, and a low power consumption and high opening rate are demanded. In order to achieve a high performance and high opening rate of the liquid crystal display device, it is necessary to thin the gate wiring and signal wiring, which serve as the first metal layer. Further, in order to achieve a low power consumption (H common reverse drive) and a built-in circuit such as of DA converter, it is necessary to lower the flat band voltage (Vfb) of the MOS capacitor portion.

If the gate wiring and signal wiring are thinned, the wiring resistance of the gate wiring or signal wiring increases, and therefore the consumption power increases, thereby reducing the circuit power margin. In order to avoid this, a low-resistance wiring material is required. Here, the thinning of a wiring line means that a typical conventional wiring width, which is in a rage of 3 μm to 5 μm, is reduced to a range of 0.5 μm to 2 μm.

In the case where a polycrystalline semiconductor layer is used for the MOS capacity portion, the following method is employed to lower the flat band voltage of the MOS capacity portion. That is, an impurity of phosphorus (P) or boron (B) is implanted to the polycrystalline semiconductor layer to make it into an n-type or p-type.

A specific example of the method of manufacturing an array substrate for a liquid crystal display device will now be described. That is, an amorphous semiconductor layer is formed on a glass substrate, and then the amorphous semiconductor layer is annealed with laser beam to convert it into a polycrystalline semiconductor layer, which is further subjected to patterning. After that, a gate insulating film is formed on the glass substrate to cover the polycrystalline semiconductor layer.

Here, the pixel auxiliary capacitor must have at least a certain amount; otherwise, the pixel auxiliary capacitance cannot be maintained. For this reason, the thickness of the gate insulating film should preferably be as small as possible. In order to achieve this, structurally, the gate insulating film is formed on the polycrystalline semiconductor layer and the layer for the gate electrode is formed on the gate insulating film. Therefore, before forming this gate electrode, the resist is patterned and an n-type dopant (PH3) is implanted by doping, thereby forming each of an n⁺-region of an n-ch thin film transistor (TFT), a pixel capacitor and a capacitor portion which serves as a capacitor region of a circuit portion.

Further, on the gate insulating film that covers all of the n⁺-region, pixel capacitor and the capacitor portion of the circuit portion, a gate electrode layer is formed, and then a gate electrode that is used for a p-ch thin film transistor (TFT) is patterned. After that, a p-type dopant (B2H5) is implanted as an impurity, thereby forming a p+-region of the p-ch thin film transistor.

Next, a gate electrode of the n-ch thin film transistor side is patterned, and each of the n-ch thin film transistor and p-ch thin film transistor is annealed. Then, the n⁺-region of the n-ch thin film transistor and p⁺-region of the p-ch thin film transistor are activated. Subsequently, an interlayer insulating film is formed on the gate insulating film that contains the gate electrodes of the n-ch and p-ch thin film transistors.

Further, contact holes are formed in the interlayer insulating film to be communicated with the n⁺-region of the n-ch thin film transistor and p⁺-region of the p-ch thin film transistor, and a conductive layer is formed on the interlayer insulating film including the contact holes. After that, the conductive layer is patterned to form a source electrode and a drain electrode which are electrically connected to the n⁺-region of the n-ch thin film transistor and p⁺-region of the p-ch thin film transistor. Such a conventional structure just described is discussed in, for example, Jpn. Pat. Appln. KOKAI Publication No. 2002-359252 (pages 7 to 10, FIGS. 8 and 9).

The gate wiring of the liquid crystal display device discussed in this document uses an alloy containing molybdenum (Mo) such as molybdenum-tungsten (MoW) or molybdenum-tantalum (MoTa). The gate electrode of this liquid crystal display device is formed such that the leads of the gate wiring, pixel capacitor wiring and circuit capacitor wiring are formed integrally in one layer.

Molybdenum alloys are conventionally used for gate electrodes as materials which have such a high thermal resistance that can fully resist annealing which is heat activation in a range of about 500° C. to 600° C. However, the resistance of a molybdenum alloy sheet having a thickness of 300 nm is high as 0.5Ω/cm², and when such a sheet is formed into a slender wire, the resistance increases even more. For this reason, it is not possible to thin the gate electrode.

In order to lower the resistance of the gate electrode, it is considered that a more general material, for example, aluminum (Al) or an aluminum alloy such as aluminum-copper (AlCu), which is a material having a lower resistance than those of the molybdenum alloys, should be employed. However, when such an aluminum alloy is used, the wiring is easily short-circuited since the temperature in the later step, thermal activation step, is high. Further, the deterioration of the resistance caused by electromigration, and a break in the wiring easily occur, creating the problem of a low reliability. More specifically, if aluminum or an aluminum alloy is annealed at a high temperature during the thermal activation, a hillock is created, thereby causing a short-circuiting between wiring lines. For this reason, it is very difficult from the point of processing to lower the resistance of the gate electrode.

On the other hand, when aluminum-neodymium (AlNd) is used, such a problem such of a low reliability does not occur even if the annealing is carried out at a temperature of 500° C. or less, but there result drawbacks of a low processing accuracy and a low productivity. More specifically, when an aluminum-neodymium material is employed and the wiring line is thinned to 2 μm or less, it is difficult to control the distribution in the wire width in a wet etching step, thereby causing a large distribution in the length of the gate electrode of the thin film transistor. This causes a distribution in the transistor characteristics of the thin film transistor. Under these circumstances, a dry etching method, which can control the distribution of the wire width, is usually employed.

However, in the case where the gate electrode of the liquid crystal display device is made of aluminum-neodymium and the gate electrode is subjected to dry etching, a great amount of etching product such as aluminum chloride (AlCl2) is attached to an inner wall surface of the chamber of the dry etching device, thereby making it difficult to improve the productivity. For this reason, it is difficult to use aluminum-neodymium as the material of the gate electrode in terms of the processing in a product in which the thinning of the gate electrode is necessary. Thus, the conventional technique entails the drawback that the gate electrode cannot be easily thinned and the resistance thereof cannot be lowered.

### BRIEF SUMMARY OF THE INVENTION

The present invention has been achieved in consideration of the above-described point, and the object is to provide an array substrate in which the first conductive layer is thinned and the resistance thereof can be lowered and a liquid crystal display device employing such an array substrate, as well as a method of manufacturing an array substrate.

According to an aspect of the present invention, there is provided an array substrate comprising:

a transparent substrate;

a plurality of polycrystal semiconductor layers provided on one main surface of the transparent substrate;

a gate insulating film provided on the main surface of the transparent substrate to cover the plurality of polycrsytal semiconductor layers;

a first conductive layer provided on the gate insulating film to face one of the plurality of polycrystal semiconductor layers via the gate insulating film; and

a second conductive layer including a wiring portion provided on one main surface of the first conductive layer and electrically connected to the first conductive layer, and a capacitor wiring portion provided on the gate insulating film to face any other one of the plurality of polycrystal semiconductor layers via the gate insulating film, and forming a capacitance between the other one of the plurality of polycrystal semiconductor layer and the capacitor wiring portion itself.

According to another aspect of the present invention, there is provided a liquid crystal display device comprising:

an array substrate including: a transparent substrate; a plurality of polycrystal semiconductor layers provided on one main surface of the transparent substrate; a gate insulating film provided on the main surface of the transparent substrate to cover the plurality of polycrsytal semiconductor layers; a first conductive layer provided on the gate insulating film to face one of the plurality of polycrystal semiconductor layers via the gate insulating film; and a second conductive layer including a wiring portion provided on one main surface of the first conductive layer and electrically connected to the first conductive layer, and a capacitor wiring portion provided on the gate insulating film to face any other one of the plurality of polycrystal semiconductor layers via the gate insulating film, and forming a capacitance between the other one of the plurality of polycrystal semiconductor layer and the capacitor wiring portion itself;

a counter substrate provided to face the array substrate; and

a liquid crystal inserted between the counter substrate and the array substrate.

According to still another aspect of the present invention, there is provided a method of manufacturing an array substrate comprising:

forming a plurality of polycrystal semiconductor layers on one main surface of a transparent substrate;

forming a gate insulating film on the main surface of the transparent substrate to cover the plurality of polycrsytal semiconductor layers;

forming a first conductive layer on one surface of the gate insulating film;

patterning the first conductive layer, thereby forming a plurality of gate electrodes facing respective ones of the plurality of polycrsytal semiconductor layers;

doping one of the polycrystal semiconductor layers which faces a respective one of the plurality of gate electrodes using the respective one of the plurality of gate electrodes, thereby forming a source region and drain region of a p-type switching element;

doping an other one of the polycrystal semiconductor layers which faces an other one of the plurality of gate electrodes using the other one of the plurality of gate electrodes, and some other of the polycrystal semiconductor layers which does not face any of the plurality of gate electrodes, thereby forming a source region and drain region of a n-type switching element, and a capacitor portion of an auxiliary capacitor;

forming a second conductive layer on the main surface of the gate insulating film to cover the plurality of gate electrodes; and

patterning the second conductive layer to form a pair of wiring portions facing the plurality of gate electrodes, respectively, and an auxiliary capacitor portion of the auxiliary capacitor facing the some other of the polycrystal semiconductor layers which does not face any of the plurality of gate electrodes.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is an explanatory cross sectional diagram illustrating a liquid crystal display device according to the first embodiment of the present invention;

FIG. 2 is an explanatory cross sectional diagram illustrating a step in the manufacture of the liquid crystal display device shown in FIG. 1, where a first conductive layer is formed on a light-transmitting substrate;

FIG. 3 is an explanatory cross sectional diagram illustrating a step in the manufacture of the liquid crystal display device, where doping is carried out on sections to be formed into source and drain regions of a p-channel type thin film transistor;

FIG. 4 is an explanatory cross sectional diagram illustrating a step in the manufacture of the liquid crystal display device, where doping is carried out on sections to be formed into source and drain regions and a capacity portion of an auxiliary capacitor of an n-channel type thin film transistor;

FIG. 5 is an explanatory cross sectional diagram illustrating a step in the manufacture of the liquid crystal display device, where a second metal layer is formed on a gate insulating film to cover a gate electrode;

FIG. 6 is an explanatory cross sectional diagram illustrating a step in the manufacture of the liquid crystal display device, where a second conductive layer is patterned;

FIG. 7 is an explanatory cross sectional diagram illustrating a step in the manufacture of the liquid crystal display device, where an interlayer insulating layer is formed on the gate insulating film containing a wiring portion and capacitor wiring portion;

FIG. 8 is an explanatory cross sectional diagram illustrating a step in the manufacture of the liquid crystal display device, where a contact hole is formed in the interlayer insulating layer;

FIG. 9 is an explanatory cross sectional diagram illustrating a step in the manufacture of the liquid crystal display device, where the conductive layers formed on the interlayer insulating layer to cover the contact hole is patterned;

FIG. 10 is an explanatory cross sectional diagram illustrating a step in the manufacture of the liquid crystal display device, where a protection film is formed in the interlayer insulating layer to cover a source electrode, a drain electrode and a leader electrode;

FIG. 11 is an explanatory cross sectional diagram illustrating a liquid crystal display device according to the second embodiment of the present invention;

FIG. 12 is an explanatory cross sectional diagram illustrating a step in the manufacture of the liquid crystal display device shown in FIG. 11, where a first interlayer insulating film is formed on a gate insulating film to cover a gate electrode;

FIG. 13 is an explanatory cross sectional diagram illustrating a step in the manufacture of the liquid crystal display device, where a contact hole is formed in the first interlayer insulating film;

FIG. 14 is an explanatory cross sectional diagram illustrating a step in the manufacture of the liquid crystal display device, where a second metal layer is formed on the first interlayer insulating film to cover the contact hole;

FIG. 15 is an explanatory cross sectional diagram illustrating a step in the manufacture of the liquid crystal display device, where a second metal layer is patterned;

FIG. 16 is an explanatory cross sectional diagram illustrating a step in the manufacture of the liquid crystal display device, where a second interlayer insulating layer is formed on the gate insulating film to cover a wiring portion and capacitor wiring portion;

FIG. 17 is an explanatory cross sectional diagram illustrating a step in the manufacture of the liquid crystal display device, where a contact hole is formed in the second interlayer insulating layer;

FIG. 18 is an explanatory cross sectional diagram illustrating a step in the manufacture of the liquid crystal display device, where the conductive layers formed on the second interlayer insulating layer to cover the contact hole is patterned; and

FIG. 19 is an explanatory cross sectional diagram illustrating a step in the manufacture of the liquid crystal display device, where a protection film is formed on the second interlayer insulating layer to cover a source electrode, a drain electrode and a leader electrode.

### DETAILED DESCRIPTION OF THE INVENTION

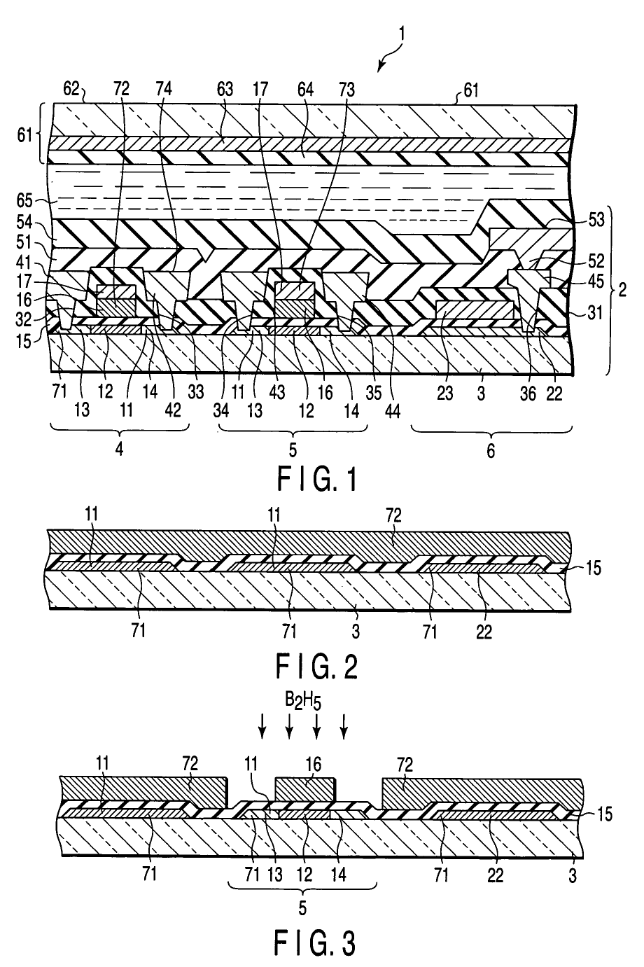

First, the structure of the liquid crystal display device according to the first embodiment of the present invention will now be described with reference to FIGS. 1 to 10.

In FIGS. 1 to 10, a liquid crystal display device 1, which is of a flat panel display type, is a thin film transistor type liquid crystal display device, and it includes a substantially rectangular flat plate shaped array substrate 2. The array substrate 2 includes a glass substrate 3, which is a transparent substrate serving as a substantially transparent rectangular flat plate-like insulating substrate. An undercoat layer, which is a stack of a silicon nitride film, a silicon oxide film, etc., is formed on an upper surface, which is one of the main surfaces, of the glass substrate 3.

A plurality of n-channel (n-ch) type thin film transistors (TFTs) 4 each serving as an n-type switching element for liquid crystal display are formed in matrix on the undercoat layer. Further, a plurality of p-channel (p-ch) type thin film transistors (TFTs) 5 each serving as a p-type switching element for liquid crystal display, a plurality of pixel auxiliary capacitors 6 each serving as an auxiliary capacitor are formed in matrix on the undercoat layer.

Here, each of the thin film transistor 4 and the respective one of the transistor 5 in pair are arranged to form a one pixel structural element. Each of a pair of a thin film transistor 4 and a respective thin film transistor 5 includes a polysilicon layer 11, which is a polycrystal semiconductor layer formed on the undercoat layer. The polysilicon layer 11 is made of polysilicon formed by annealing amorphous silicon, which is an amorphous semiconductor, with laser beam. The polysilicon layer 11 includes a channel region 12 provided at a central portion of the polysilicon layer 11 and serving as an activated layer. On both sides of the channel region 12, a source region 13 and a drain region 14, which are n⁺-regions or p⁺-regions, are formed respectively to face each other.

A gate insulating film 15, which is a silicon oxide film with an insulating property, is stacked on the undercoat layer to cover the channel region 12, source region 13 and drain region 14. Further, a gate electrode 16, which is made of a first metal layer 72 serving as a first conductive layer, is stacked on a section of the gate insulating film 15, which opposes to the channel region 12. The first metal layer 72 is made of an alloy containing molybdenum (Mo), more specifically, molybdenum-tungsten (MoW). The respective gate electrode 16 faces the channel region 12 of the thin film transistors 4 and 5 via the gate insulating film 15, and has a width substantially the same as that of the channel region 12.

A wiring portion 17 serving as gate wiring is stacked on each gate electrode 16. The wiring portion 17 is made of a second metal layer 73 serving as the second conductive layer. Each wiring portion 17 is electrically connected to each respective gate electrode 16, and is a wiring portion provided between gate electrodes, having the same width as that of each gate electrode 16. Note that each wiring portion 17 is made of a material having a resistance value lower than that of each gate electrode 16.

Meanwhile, a pixel auxiliary capacitor 6 made of polysilicon is stacked on the undercoat layer that is continued to the thin film transistors 4 and 5. The pixel auxiliary capacitor 6 is provided adjacent to the p-channel type thin film transistor 5, which is on an opposite side to the n-channel type thin film transistor 4 with respect to the thin film transistor 5.

The pixel auxiliary capacitor 6 is arranged on the same plane as that of the thin film transistors 4 and 5 formed on the glass substrate 3. The pixel auxiliary capacitor 6 comprises a capacitor portion. The capacitor portion 22 is made of polysilicon formed by annealing amorphous silicon, which is an amorphous semiconductor, with laser beam. The capacitor portion 22 is formed in the same step for forming the polysilicon layer 11 of each of the thin film transistors 4 and 5, and it is stacked on the undercoat layer.

A gate insulating film 15 is stacked on the undercoat layer to cover the capacitor portion 22. On a portion of the gate insulating film 15, which opposes to the capacitor portion 22, a capacitor wiring portion 23 made of the second metal layer 73 is stacked. Note that the second metal layer 73 is the same layer as that of the thin film transistors 4 and 5. The capacitor wiring portion 23 is arranged on one side of the capacitor portion 22 in its width direction, which is on the p-channel type thin film transistor 5 side. In other words, the capacitor wiring portion 23 is arranged at a site closer to the p-channel type thin film transistor 5 with respect to the central portion of the capacitor portion 22 in its width direction.

Each of thus formed capacitor wiring portions 23 forms a capacitor between itself and a respective capacitor portion 22 via a respective gate insulating film 15 between the capacitor wiring portion 23 and the respective capacitor portion 22. Each of the capacitor wiring portions 23 is formed in the same step and of the same material as those of the wiring portions 17 of the thin film transistors 4 and 5. Therefore, the capacitor wiring portions 23 have a resistance value lower than that of the wiring portions 17 of the thin film transistors 4 and 5.

An interlayer insulating film 31 serving as a silicon oxide film having an insulating property is stacked on the gate insulating films 15 to cover each of the capacitor wiring portions 23 and the wiring portions 17 of the thin film transistors 4 and 5. In the interlayer insulating films 31 and gate insulating films 15, contact holes 32, 33, 34, 35 and 36 are formed respectively as conductive portions made through these films.

The contact holes 32 and 33 are formed above the source region 13 and drain region 14 of the thin film transistor 4, which are situated on the respective sides of the gate electrode 16 of the n-channel type thin film transistor 4. The contact hole 32 is opened to communicate to the source region 13 of the n-channel type thin film transistor 4, and the contact hole 33 is opened to communicate to the drain region 14 of the n-channel type thin film transistor 4.

The contact holes 34 and 35 are formed above the source region 13 and drain region 14 of the thin film transistor 5, which are situated on the respective sides of the gate electrode 16 of the p-channel type thin film transistor 5. The contact hole 34 is opened to communicate to the source region 13 of the p-channel type thin film transistor 5, and the contact hole 35 is opened to communicate to the drain region 14 of the p-channel type thin film transistor 5. The contact hole 36 is opened to communicate to the capacitor portion 22 of the pixel auxiliary capacitor 6.

A source electrode 41 is stacked in the contact hole 32 communicating to the source region 13 of the n-channel type thin film transistor 4. The source electrode 41 is a signal line that serves as a conductive layer. The source electrode 41 is electrically connected to the source region 13 of the n-channel type thin film transistor 4 via the contact hole 32. A drain electrode 42 is stacked in the contact hole 33 communicating to the drain region 14 of the n-channel type thin film transistor 4. The drain electrode 42 is a signal line that serves as a conductive layer. The drain electrode 42 is electrically connected to the drain region 14 of the n-channel type thin film transistor 4 via the contact hole 33.

A source electrode 43 is stacked in the contact hole 34 communicating to the source region 13 of the p-channel type thin film transistor 5. The source electrode 43 is a signal line that serves as a conductive layer. The source electrode 43 is electrically connected to the source region 13 of the p-channel type thin film transistor 5 via the contact hole 34. A drain electrode 44 is stacked in the contact hole 35 connecting to the drain region 14 of the p-channel type thin film transistor 5. The drain electrode 44 is a signal line that serves as a conductive layer. The drain electrode 44 is electrically connected to the drain region 14 of the p-channel type thin film transistor 5 via the contact hole 33. A lead electrode 45 is stacked in the contact hole 36 communicating to the capacitor portion 22 of the pixel auxiliary capacitor 6. The lead electrode 45 is made of a conductive layer that serves as a gate lead wiring.

On the other hand, a protection film 51 is stacked on the interlayer insulating film 31 that contains the source electrodes 41 and 43 and drain electrodes 42 and 44 of the thin film transistors 4 and 5, and the lead electrode 45 of the pixel auxiliary capacitor 6 such as to cover each of the thin film transistors 4 and 5 and the pixel auxiliary capacitor 6. A contact hole 52 is opened in the protection film 51 to pierce through the film to made a conductive portion. The contact hole 52 is opened to communicate to the lead electrode 45 of the pixel auxiliary capacitor 6.

A plurality of pixel electrodes 53 are stacked on the protection film 51 to cover the contact hole 52. A pixel electrode 53 is electrically connected to the lead electrode 45 via the contact hole 52. That is, the pixel electrode 53 is electrically connected to the capacitor portion 22 of the pixel auxiliary capacitor 6 via the lead electrode 45. The pixel electrode 53 is controlled by either one of the thin film transistors 4 and 5. Further, an alignment film 54 is stacked on the protection film 51 including the pixel electrodes 53.

On the other hand, a rectangular plate-shaped counter substrate 61 is arranged opposite to the array substrate 2. The counter substrate 61 includes a glass substrate 62, which is a transparent substrate serving as a substantially transparent insulating substrate having a rectangular plate shape. A counter electrode 63 is provided on one main surface of the glass substrate 62, which is on the side facing the array substrate 2. Further, an alignment film 64 is stacked on the counter substrate 63. Furthermore, liquid crystal 65 is held between the alignment film 64 of the counter substrate 61 and the alignment film 54 of the array substrate 2.

Next, the method of manufacturing an array substrate according to the first embodiment will now be described.

First, an amorphous silicon film having a thickness of 50 nm is formed on a glass substrate 3 using a CVD (chemical vapor deposition) method. The amorphous silicon film is made of amorphous silicon, which is an amorphous semiconductor. Then, excimer laser beam is applied to the amorphous silicon film on the glass substrate 3 (that is, annealing with laser beam) for crystallization to transform the amorphous silicon film into a polysilicon film 71, which is a polysilicon semiconductor layer. Here, it is preferable that the thickness of the polysilicon film 71 should be set in a range of 40 nm to 80 nm.

Next, diborane (B2H5) is injected into the polysilicon film 71 by doping, and made into an island-like manner by a photolithography step. Here, the concentration of boron injected to the polysilicon film 71 is set to 10¹⁶/cm³ or more and 10¹⁷/cm³ or less. With the injection of boron to the polysilicon film 71, the threshold voltage of each of the thin film transistors 4 and 5 becomes controllable.

Further, a gate insulating film 15 having a thickness of 100 nm is formed on the glass substrate 3 including the island-like polysilicon film 71 by a PE (plasma enhanced)-CVD method.

Next, as shown in FIG. 2, a molybdenum-tungsten alloy (MoW) film having a thickness of 300 nm is formed on the gate insulating film 15, thereby forming a first metal layer 72 serving as the first conductive layer. The molybdenum-tungsten alloy (MoW) film gives rise to the gate electrode 16 of each of the thin film transistors 4 and 5. Here, the sheet resistance of the first metal layer 72 is 0.5Ω/cm². Note that other than molybdenum-tungsten (MoW), the first metal layer 72 may as well be made by forming a molybdenum-tantalum (MoTa) film.

After that, a resist which is not shown in the figure is patterned to cover the section excluding the portions which give rise to the source region 13 and drain region 14 on the both sides of the gate electrode 16 of the p-channel type thin film transistor 5 with the photolithography process. Then, the first metal layer 72 is etched by plasma using a mixture gas containing fluorine and oxygen to remove the portions on both sides of the polysilicon layer 11 of the thin film transistor 5. Here, the wiring width of the p-channel gate electrode 16 is set to 1.0 μm or more and 2.0 μm or less.

After the plasma etching, the resist on the gate insulating film 15 is removed with an organic alkali solution.

Then, as shown in FIG. 3, a p-type dopant, namely, diboran (B2H5) is implanted by doping to the portions that give rise to the source region 13 and drain region 14 of the p-channel type thin film transistor 5 using the first metal layer 72 remaining after the plasma etching. Note that the doping of diboran is carried out to lower the resistance value of the polysilicon layer 11 and to have an ohmic contact with the metal. The implantation of diboran to the polysilicon layer 11 is carried out at an acceleration voltage of 50 keV and a dose amount of 10¹⁵ cm⁻².

Next, a resist which is not shown in the figure is patterned to cover the portions which give rise to the gate electrode 16 of the n-channel type thin film transistor 4, and the p-channel type thin film transistor 5 with the photolithography process. Then, the first metal layer 72 is etched by plasma using a mixture gas containing fluorine and oxygen to remove the portions that give rise to the source region 13 and drain region 14 of the n-channel type thin film transistor 4, and the pixel auxiliary capacitor 6. Here, the width of the wiring of the gate electrode 16 of the n-channel type thin film transistor 4 is set to 1.0 μm or more and 2.0 μm or less as well.

After the plasma etching, the resist on the gate insulating film 15 is removed with an organic alkali solution.

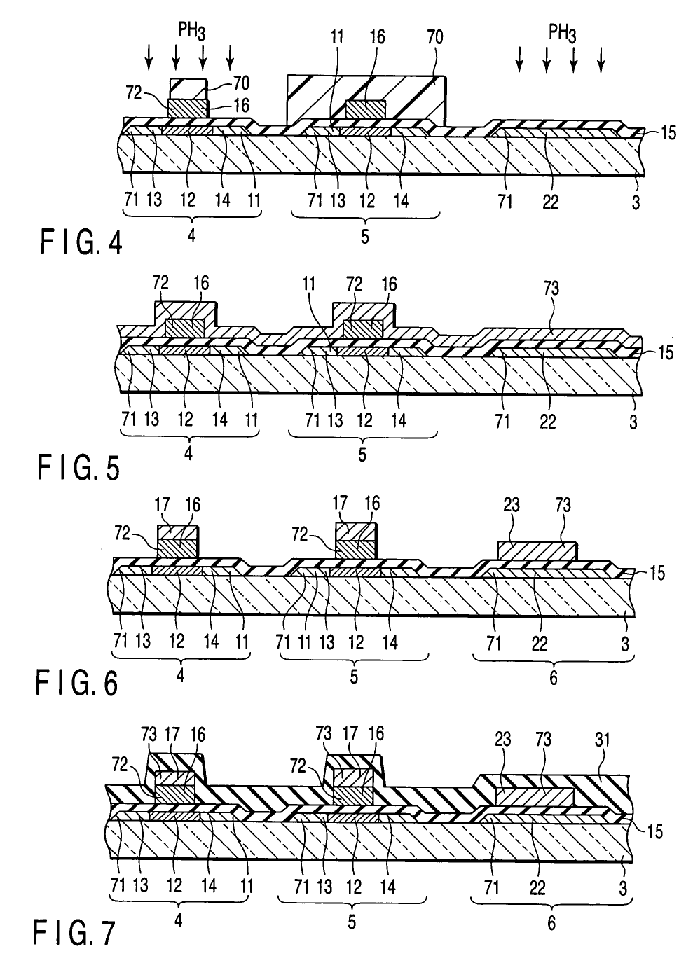

Then, as shown in FIG. 4, a resist 70 is patterned on the portions which give rise to the gate electrode 16 of the n-channel type thin film transistor 4, and the p-channel type thin film transistor 5 in the first metal layer 72 with the photolithography process. Then, a n-type dopant, namely, phosphine (PH3) is implanted by doping to the portions of the polysilicon layer 11 that give rise to the source region 13 and drain region 14 of the n-channel type thin film transistor 4 and the capacitor portion 22 of the pixel auxiliary capacitor 6. Note that the implantation of phosphine to the polysilicon layer 11 is carried out at an acceleration voltage of 70 keV and a dose equivalent of 10¹⁵ cm⁻².

Here, in order to make the n-channel type thin film transistor 4 into an LDD (lightly doped drain) structure, it is possible that the portion of the first metal layer 72 which gives rise to the gate electrode 16 of the n-channel type thin film transistor 4 is etched once again to reduce the thickness, and a n-type dopant is lightly doped to form a n⁻ region.

With use of the first metal layer 72 that gives rise to the gate electrode 16 of the n-channel type thin film transistor 4 as the same mask, heavy doping and light doping are both carried out. Therefore, the length of the LDD region can be decreased, and further the transistor characteristics (ion properties) of the n-channel type thin film transistor 4 can be improved.

After that, the source region 13 and drain region 14 of each of the n-channel type thin film transistor 4 and the p-channel type thin film transistor 5, and the capacitor portion 22 of the pixel auxiliary capacitor 6 are subjected to annealing process at a temperature of 400° C. or higher and 500° C. or lower, thereby activating the source regions 13, the drain regions 14 and the capacitance portion 22. Here, the sheet resistance of each of the p⁺ regions of the p-channel type thin film transistor 5, that is, the source region 13 and drain region 14, is set to 3 kΩ/cm², and the sheet resistance of each of the n⁺ regions of the n-channel type thin film transistor 4, that is, the source region 13 and drain region 14, is set to 2 kΩ/cm².

Next, as shown in FIG. 5, a second metal layer 73 is formed directly on the gate insulating film 15 that includes the gate electrodes 16 of the thin film transistors 4 and 5. The second metal layer 73 is made of a low-resistance material film and serves as the second conductive layer that gives rise to a wiring portion 17 connecting the gate electrodes 16 of the transistors 4 and 5 to each other, and a capacitor wiring portion 23 of the pixel auxiliary capacitor 6.

It should be noted that the second metal layer 73 has a stack structure of three layers of titanium (Ti)/aluminum-copper (AlCu)/titanium (Ti) having thickness of 50 nm/300 nm/75 nm, respectively. The sheet resistance of the second metal layer 73 is set to 0.12Ω/cm². It is alternatively possible that the second metal layer 73 has a five-layer structure of titanium (Ti)/titanium nitride (TiN)/aluminum-copper (AlCu)/titanium (Ti)/titanium nitride (TiN), or a structure in which aluminum-copper is replaced by pure aluminum (that is, for example, Ti/Al/Ti) or a structure of aluminum-neodymium (AlNd)/molybdenum (Mo).

After that, as shown in FIG. 6, the second metal layer 73 is patterned in a photolithography process to form the wiring portion 17 that connects the gate electrodes of the first metal layer 72 and the capacitor wiring portion 23. Here, if the second metal layer 73 contains aluminum (Al) or aluminum-copper (AlCu), dry etching is performed using a metal chlorine-based gas. If the second metal layer 73 contains aluminum-neodymium (AlNd), wet etching is carried out.

Next, as shown in FIG. 7, a silicon oxide film having a thickness of 600 nm is formed on the gate insulating film 15 including the wiring portions 17 and capacitor wiring portion 23, which serves as an interlayer insulating film 31 by a PE-CVD method.

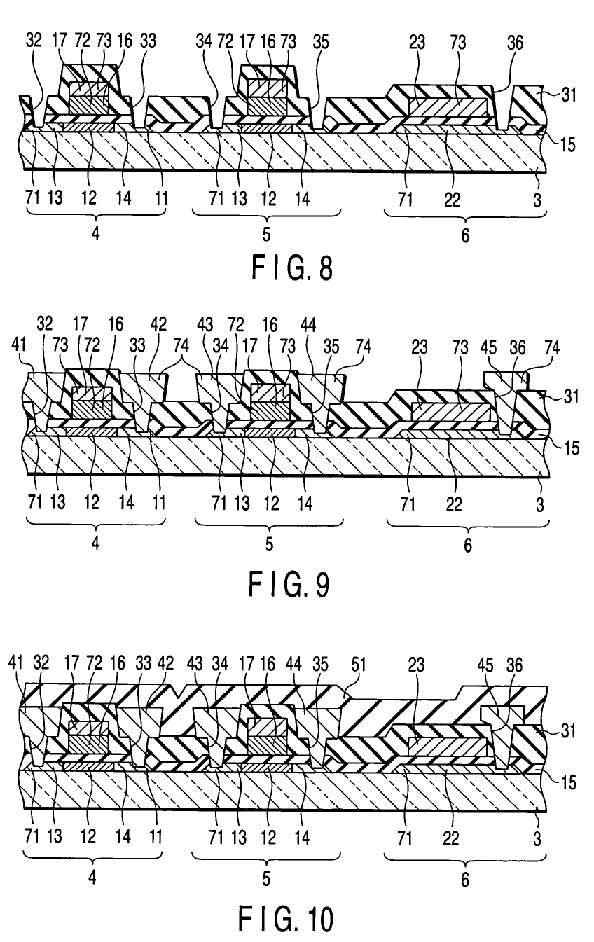

Subsequently, as shown in FIG. 8, contact holes 32, 33, 34, 35 and 36 are made connecting to the source region 13 and drain region 14 of each of the thin film transistors 4 and 5, and the capacitor portion 22 of the pixel auxiliary capacitor 6, respectively, with the photolithography process.

After that, a stack layer film of, for example, a molybdenum (Mo) layer having a thickness of 50 nm and an aluminum (Al) layer having a thickness of 500 nm is formed by a sputtering method on the interlayer insulating film 31 including each of the contact holes 32, 33, 34, 35 and 36. The stack layer serves as a conductive layer 74 which gives rise to a signal line wiring.

Subsequently, as shown in FIG. 9, the conductive layer 74 is etched by the photolithographic process to form source electrodes 41 and 43, drain electrodes 42 and 44 and a lead electrode 45. Here, in the case where the conductive layer 74 is formed of a metal material such as aluminum (Al) or aluminum-copper (AlCu), it is patterned by etching with chlorine gas.

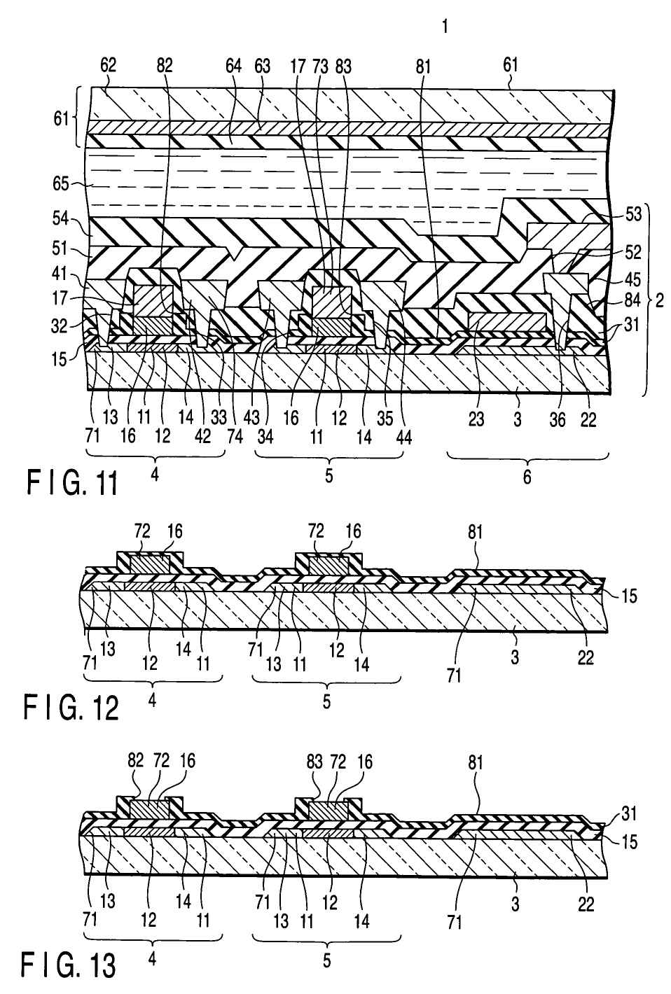

Further, as shown in FIG. 10, a silicon nitride film having a thickness of 500 nm is formed by a PE CVD method on an entire surface of the interlayer insulating film 31 including the source electrodes 41 and 43, drain electrodes 42 and 44 and lead electrode 45. This silicon nitride film is a protection film 51.

Subsequently, the protection film 51 is etched in a photolithography process, to form in the protection film 51 a contact hole 52 that continues to the lead electrode 45 of the pixel auxiliary capacitor 6. For the etching, plasma etching that uses tetrafluoromethane (CF4) gas and oxygen gas is employed.

After that, a pixel electrode 53, which is a transparent conductive film, is formed by sputtering on the protection film 51 to cover the contact hole 52. Then, with a photolithography process and etching process, the pixel electrode 53 is patterned into a pixel shape. For the etching of the pixel electrode 53, oxalic acid (HOOC—COOH) is used.

Here, conventionally, the gate electrodes of the n-channel type thin film transistor and p-channel thin film transistor are each formed to have a two-layer structure, thereby connecting the wiring portions that are made of a low-resistance metal. In the just-mentioned conventional case, as the process for forming the second metal layer, a photolithography process, n⁺ doping process and resist removing process are added to form the capacitor portion in addition to the film forming process, photolithography process and etching process. Thus, the number of steps is increased, thereby deteriorating the productivity.

Especially, in the case where a pixel auxiliary capacitor is made of a capacitor portion made of polysilicon, a gate insulating film and a gate electrode, it is conventionally required to implant phosphine (PH3) as an n-type dopant by doping to the polysilicon layer portion that will give rise to the capacitor portion before the gate electrode is formed.

As a solution, the first embodiment is proposed, in which the pixel auxiliary capacitor 6 includes the capacitor portion 22 made of polysilicon, the gate insulating film 15 and the capacitor wiring portion 23, which is a low-resistance wiring portion. In this embodiment, the n⁺ doping operation for forming the capacitor portion 22 of the pixel auxiliary capacitor 6 is carried out at the same time in the same step for forming the source region 13 and drain region 14 of the n-channel type thin film transistor 4.

As a result, the capacitor forming process, which includes the photolithography step, n⁺ doping step and resist removing step, can be omitted. Thus, the width of the gate electrode 16 can be reduced and their resistance can be lowered while the number of steps is reduced to the minimum. As a whole, the liquid crystal display device 1 can achieve a high resolution, a high aperture and a low power consumption, and at the same time, conventional memory circuits and drive circuits that are mounted by TAB can be built in the liquid crystal display device 1 as it is conventionally so.

Further, each of the n-channel type thin film transistor 4 and p-channel type thin film transistor 5 is formed to have a two-layer structure of the gate electrode 16 and wiring portion 17. Therefore, the gate electrode 16, which must be formed before the heat activation, is made of a heat resistive material, and the second metal layer 73 is made of a low resistance material for the long run portion of the capacitor wiring portion 23 of the pixel auxiliary capacitor 6 after the heat activation. In this manner, a resisting wire for the gate electrode 16 of each of the thin film transistors 4 and 5 can be made finely narrow and low resistive.

As described above, the gate electrode 16 of each of the thin film transistors 4 and 5 is formed to have a two-layer structure, and the structure of the pixel auxiliary capacitor 6 is changed. With this arrangement, the resistance of the gate electrodes 16 of the thin film transistors 4 and 5 can be lowered while suppressing the increase in the number of steps for forming the array substrate 2 to a minimum.

Next, the structure of a liquid crystal display device according to the second embodiment of the present invention will now be descried with reference to FIGS. 11 to 19.

A liquid crystal display device 1 shown in FIGS. 11 to 19 is basically similar to the liquid crystal display device 1 shown in FIGS. 1 to 10 except for the following aspects. That is, a first interlayer insulating film 81 is formed on a gate insulating film 15 to cover gate electrodes 16, and then contact holes 82 and 83 are formed as conducting portions connecting to the respective gate electrodes 16 in the first interlayer insulating film 81. After that, a second metal layer 73 is formed on the first interlayer insulating film 81 to cover the contact holes 82 and 83.

In other words, the liquid crystal display device 1 has such a structure that an interlayer insulating film 31 is formed to have two layer divisions of the first interlayer insulating film 81 and second interlayer insulating film 84, and a second metal layer 73 is formed between the first interlayer insulating film 81 and second interlayer insulating film 84. That is, in the liquid crystal display device 1, the first metal layer 72 is formed, and then the second metal layer 73 is formed via the first interlayer insulating film 81.

The first interlayer insulating film 81 is stacked on the gate insulating film 15 to cover each of the gate electrodes 16. Further, the contact holes 82 and 83 are formed in the first interlayer insulating film 81 to pierce in the direction perpendicular to the surface direction at the positions located above the respective gate electrodes 16. Each of the contact holes 82 and 83 has the same width as that of the gate electrodes 16. In the contact holes 82 and 83, wiring portions 17 are formed respectively. Each of the wiring portions 17 is electrically connected to the respective one of the gate electrodes 16.

A second interlayer insulating film 84 is stacked on the first interlayer insulating film 81 to cover the wiring portions 17 and capacitor wiring portion 23. Contact holes 32, 33, 34, 35 and 36 are opened in the second interlayer insulating film 84, first interlayer insulating film 81 and gate insulating film 15 to pierce through each of these films in the up-and-down directions, which is a vertical direction normal to the surface direction of each.

Next, a method of manufacturing an array substrate according to the second embodiment will now be described.

Note that the steps up to the formation of the gate electrodes 16 on the gate insulating film 15 are similar to those of the first embodiment shown in FIGS. 2 to 4.

After that step, as shown in FIG. 12, a silicon oxide film having a thickness of 50 nm, which gives rise to the first interlayer insulating film 81, is formed by the PE-CVD method on the gate insulating film 15 to cover each of the gate electrodes 16. Here, the thickness of the first interlayer insulating film 81 is determined such that the capacitance value at the pixel auxiliary capacitor 6 is larger than that indicated in the product specification.

Next, as shown in FIG. 13, the contact holes 82 and 83 are formed in the first interlayer insulating film 81 by the photolithography step in order for the coupling to the respective gate electrodes 16.

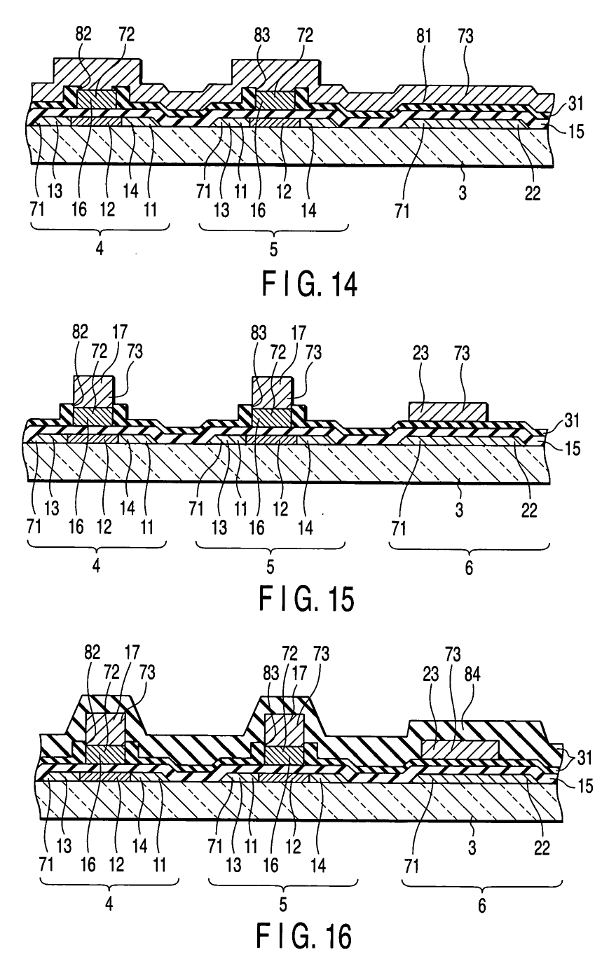

After that, as shown in FIG. 14, the second metal layer 73 made of a low resistance material film, which gives rise to the wiring portions 17 connecting the gate electrodes 16, and the capacitor wiring portion 23 of the pixel auxiliary capacitor 6, is formed on the first interlayer insulating film 81 to cover the contact holes 82 and 83. Subsequently, as shown in FIG. 15, the photolithography step and etching step are carried out in this order. The photolithography step and etching step carried out here are similar to those of the first embodiment.

Further, as shown in FIG. 16, a silicon oxide film having a thickness of 600 nm, which serves as the second interlayer insulating film 84, is formed on the first interlayer insulating film 81 to cover each of the wiring portions 17 and capacitor wiring portion 23.

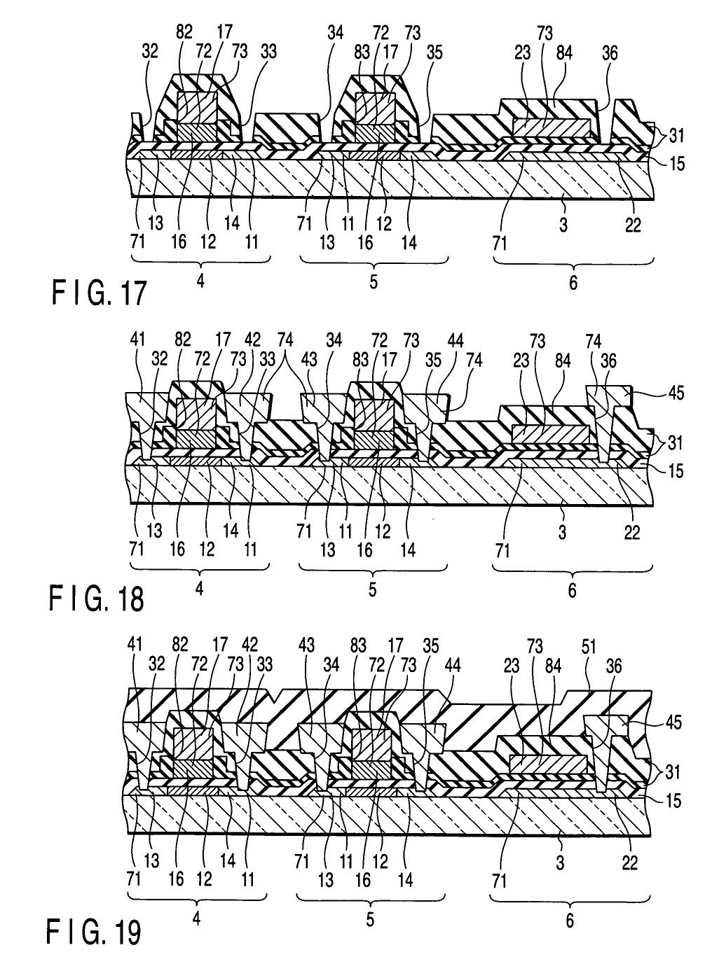

After that, as shown in FIG. 17, a plurality of contact holes 32, 33, 34, 35 and 36 are formed by the photolithography process in the second interlayer insulating film 84, the first interlayer insulating film 81 and the gate insulating film 15, respectively, to pierce therethrough.

Subsequently, as shown in FIG. 18, the conductive layer 74, which serves as the signal line wiring portion, is formed on the second interlayer insulating film 84 to cover each of these contact holes 32, 33, 34, 35 and 36. Then, the conductive layer 74 is etched by the photolithography process to form the source electrodes 41 and 43, drain electrodes 42 and 44, and lead electrode 45.

Next, as shown in FIG. 19, a silicon nitride film that gives rise to the protection film 51 is formed by the PE-CVD method on an entire surface of the interlayer insulating film 31 to cover the source electrodes 41 and 43, drain electrodes 42 and 44 and lead electrode 45.

After that, the protection film 51 is etched by the photolithography process to form the contact hole 52, and then the pixel electrode 53 is formed on the protection film 51 including the contact hole 52.

As described above, according to the second embodiment, the interlayer insulating film 31 is formed to have a two-layer structure of the first interlayer insulating film 81 and the second interlayer insulating film 84. Therefore, as compared to the first embodiment, the number of the processing steps is larger by those for forming the contact holes 82 and 83. However, at the same time, when the second metal layer 73 is being etched, the gate electrode 16 of the first metal layer 72 is protected by the first interlayer insulating film 81. As a result, it is not necessary in this embodiment to carry out a high selection ratio etching, thereby making it possible to facilitate the etching process for the second metal layer 73.

When the gate electrodes 16 of the first metal layer 72 are formed by etching, the gate insulating film 15 is over-etched by about 30 nm. Therefore, in the case where high-performance thin film transistors 4 and 5 are formed to include these gate electrodes 16 and gate insulating film 15, the overetched gate insulating film 15 causes the problem that the thickness of the portion of the gate insulating film 15 that gives rise to the pixel auxiliary capacitor 6 becomes thin.

In the case where the polysilicon film 71 is formed by laser anneal, projections may be undesirably formed on the surface of the polysilicon film 71. Therefore, if the thickness of the portion of the gate insulating film 15 which give rise to the capacitor portion 22 of the pixel auxiliary capacitor 6, the capacitor 22 formed from the polysilicon film 71 and the capacitor wiring portion 23 formed from the second metal layer 73 are not sufficiently insulated from each other, thereby causing a leakage between the capacitor portion 22 and the capacitor wiring portion 23. As a result, a point defect is created in the liquid crystal display device 1, which may results in the lowering of the yield.

Therefore, with the second embodiment, the productivity can be improved particularly in the case where the thickness of the gate insulating film 15 used in the liquid crystal display device 1 is small (for example, 90 nm or less).

It should be noted that in each of the embodiments described above, the capacitance between the capacitor portion 22 of the pixel auxiliary capacitor 6 and the capacitor wiring portion 23 is used as the circuit portion capacitor for driving the liquid crystal display device 1.

The first metal layer 72 may be made of another alloy containing molybdenum, that is, either one of molybdenum-tungsten (MoW) and molybdenum-tantalum (MoTa).

The second metal layer 73 may be made of a stack film of an alloy containing aluminum (Al), that is, aluminum (Al) and aluminum-copper (AlCu), and at least one of molybdenum (Mo), titanium (Ti) and titanium nitride (TiN).

With the present invention, the thickness and resistance of the gate wiring can be narrowed and lowered respectively while suppressing the number of processing steps to a minimum. Therefore, a high definition, high aperture and low consumption power of the liquid crystal display device can be achieved. At the same time, it becomes possible to produce a liquid crystal display device that includes thin film transistors equipped with memory circuits and drive circuits that are conventionally mounted by TAB.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. An array substrate comprising:
a transparent substrate;
a plurality of polycrystal semiconductor layers provided on one main surface of the transparent substrate;
a gate insulating film provided on the main surface of the transparent substrate to cover the plurality of polycrsytal semiconductor layers;
a first conductive layer provided on the gate insulating film to face one of the plurality of polycrystal semiconductor layers via the gate insulating film; and
a second conductive layer including a wiring portion provided on one main surface of the first conductive layer and electrically connected to the first conductive layer, and a capacitor wiring portion provided on the gate insulating film to face any other one of the plurality of polycrystal semiconductor layers via the gate insulating film, and forming a capacitance between the other one of the plurality of polycrystal semiconductor layer and the capacitor wiring portion itself.

2. The array substrate according to claim 1, wherein the second conductive layer has a resistance value lower than that of the first conductive layer.

3. The array substrate according to claim 1, wherein the first conductive layer is made of an alloy containing molybdenum and the second conductive layer is made of an alloy containing aluminum.

4. The array substrate according to claim 1, wherein the first conductive layer is made of one of molybdenum-tungsten and molybdenum-tantalum, and
the second conductive layer is made of a stack film of at least one of aluminum and aluminum-copper, and at least one of molybdenum, titanium and titanium nitride.

5. The array substrate according to claim 1, wherein the polycrystal semiconductor layer facing the capacitor wiring portion is doped with either one of a p-type dopant and n-type dopant.

6. A liquid crystal display device comprising:
an array substrate according to claim 1;
a counter substrate provided to face the array substrate; and
a liquid crystal inserted between the counter substrate and the array substrate.

7. A method of manufacturing an array substrate comprising:
forming a plurality of polycrystal semiconductor layers on one main surface of a transparent substrate;
forming a gate insulating film on the main surface of the transparent substrate to cover the plurality of polycrsytal semiconductor layers;
forming a first conductive layer on one surface of the gate insulating film;
patterning the first conductive layer, thereby forming a plurality of gate electrodes facing respective ones of the plurality of polycrsytal semiconductor layers;
doping one of the polycrystal semiconductor layers which faces a respective one of the plurality of gate electrodes using the respective one of the plurality of gate electrodes, thereby forming a source region and drain region of a p-type switching element;
doping an other one of the polycrystal semiconductor layers which faces an other one of the plurality of gate electrodes using the other one of the plurality of gate electrodes, and some other of the polycrystal semiconductor layers which does not face any of the plurality of gate electrodes, thereby forming a source region and drain region of a n-type switching element, and a capacitor portion of an auxiliary capacitor;
forming a second conductive layer on the main surface of the gate insulating film to cover the plurality of gate electrodes; and
patterning the second conductive layer to form a pair of wiring portions facing the plurality of gate electrodes, respectively, and an auxiliary capacitor portion of the auxiliary capacitor facing the some other of the polycrystal semiconductor layers which does not face any of the plurality of gate electrodes.

8. The method of manufacturing an array substrate, according to claim 7, wherein the second conductive layer is formed directly on the main surface of the gate insulating film to include the plurality of gate electrodes.

9. The method of manufacturing an array substrate, according to claim 7, further comprising:
forming an interlayer insulating film on the main surface of the gate insulating film to cover the plurality of gate electrodes;
forming a plurality of conductive portions in the interlayer insulating film, which connect to the plurality of gate electrodes; and
forming the second conductive layer on the interlayer insulating film to cover the plurality of conductive portions, thereby electrically connecting the second conductive layer to the plurality of gate electrodes.
